(19) United States
(12) Patent Application Publication
(10) Pub. No.: US 2025/0297160 A1
(43) Pub. Date: Sep. 25, 2025

(54) SUBSTRATE PROCESSING METHOD AND SUBSTRATE PROCESSING APPARATUS

(71) Applicant: Tokyo Electron Limited, Tokyo (JP)

(72) Inventors: Tuhin Shuvra Basu, Albany, NY (US); Hiroto FUJIKAWA, Yamanashi (JP); Atsushi ENDO, Yamanashi (JP)

(21) Appl. No.: 19/076,038

(22) Filed: Mar. 11, 2025

(30) Foreign Application Priority Data
Mar. 21, 2024 (JP) 2024-044334

(51) Int. Cl. C09K 13/08

(52) U.S. Cl. CPC C09K 13/08

(57) ABSTRACT

A method of processing a substrate, the method includes preparing the substrate in which a titanium nitride film and a titanium oxide film are stacked in this order, and supplying an etching gas containing a hydrogen fluoride gas to the substrate to etch the titanium oxide film.

### CROSS-REFERENCE TO RELATED APPLICATIONS

The present application is based on and claims priority to Japanese patent application no. 2024-044334 filed on Mar. 21, 2024, with the Japanese Patent Office, the entire contents of which are hereby incorporated by reference.

### TECHNICAL FIELD

The disclosures herein relate to substrate processing methods and substrate processing apparatuses.

### BACKGROUND

A technology is disclosed in which light is irradiated onto a portion of titanium formed on an etching target layer to form a titanium oxide film, and a pattern is subsequently formed on the etching target layer by using difference in etching rates (see, e.g., Patent Literature (PTL) 1).

### CITATION LIST

### Patent Literature

[PTL1] Japanese Laid-Open Patent Publication No. 2004-311936

### SUMMARY

A method of processing a substrate, the method includes preparing the substrate in which a titanium nitride film and a titanium oxide film are stacked in this order, and supplying an etching gas containing a hydrogen fluoride gas to the substrate to etch the titanium oxide film.

### BRIEF DESCRIPTION OF THE DRAWINGS

FIG. 1 is a flowchart illustrating a substrate processing method according to an embodiment;

FIG. 2A is a cross-sectional view illustrating a substrate prepared for the substrate processing method;

FIG. 2B is a cross-sectional view illustrating forming a titanium nitride film on the substrate;

FIG. 2C is a cross-sectional view illustrating a titanium oxide film formed on a surface of the titanium nitride film;

FIG. 2D is a cross-sectional view illustrating etching and removing the titanium oxide film;

FIG. 3 is a cross-sectional view illustrating an example of an etching step;

FIG. 4A is a cross-sectional view illustrating supplying a gas mixture to the substrate in another etching step;

FIG. 4B is a cross-sectional view illustrating heat treating the substrate in the other etching step;

FIG. 5 is a cross-sectional view illustrating a substrate processing apparatus according to the embodiment;

FIG. 6 is a drawing illustrating an example of a result of measuring oxygen concentration;

FIG. 7 is a drawing illustrating an example of a result of measuring fluorine concentration;

FIG. 8 is a drawing (1) illustrating a result of measuring an etching amount of each film; and

FIG. 9 is a drawing (2) illustrating the result of measuring the etching amount of each film.

### DETAILED DESCRIPTION

In the following, embodiments of the present invention will be described with reference to the accompanying drawings. In the drawings, the same or corresponding constituent elements are denoted with the same reference numerals, and redundant descriptions will be omitted.

### [Substrate Processing Method]

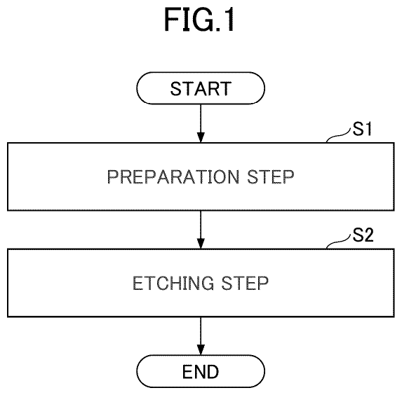

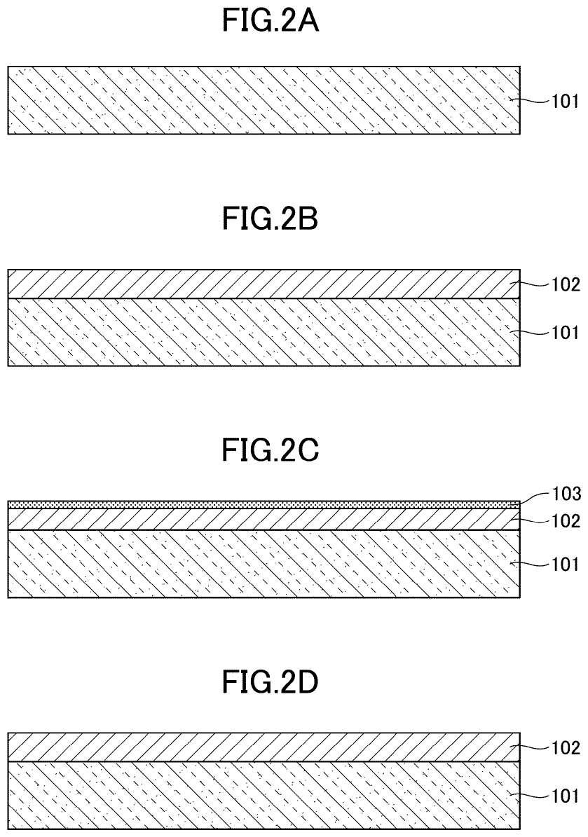

A substrate processing method according to an embodiment will be described with reference to FIGS. 1 to 4B. FIG. 1 is a flowchart illustrating the substrate processing method according to the embodiment. FIGS. 2A to 2D are cross-sectional views illustrating an example of the substrate processing method according to the embodiment.

As shown in FIG. 1, the substrate processing method according to the embodiment includes a preparation step S1 and an etching step S2.

In the preparation step S1, first, as shown in FIG. 2A, a substrate 101 is prepared. The substrate 101 is, for example, a silicon substrate. Next, as shown in FIG. 2B, a titanium nitride film 102 is formed on the substrate 101. The titanium nitride film 102 can be formed by, for example, chemical vapor deposition (CVD) or physical vapor deposition (PVD). Next, the titanium nitride film 102 formed on the substrate 101 is exposed to an oxidizing atmosphere. As a result, as shown in FIG. 2C, the surface of the titanium nitride film 102 is oxidized, and a titanium oxide film 103 which is a natural oxide film is formed. As a result, the substrate 101 in which the titanium nitride film 102 and the titanium oxide film 103 are stacked in this order is formed. The oxidizing atmosphere is, for example, an air atmosphere. In the preparation step S1, instead of exposing the titanium nitride film 102 to the oxidizing atmosphere, the titanium oxide film 103 may be formed on the substrate 101 by, for example, CVD or PVD.

The etching step S2 is performed after the preparation step S1. In the etching step S2, as shown in FIG. 2D, etching gas containing hydrogen fluoride (HF) gas is supplied to the substrate 101, and the titanium oxide film 103 is etched and removed.

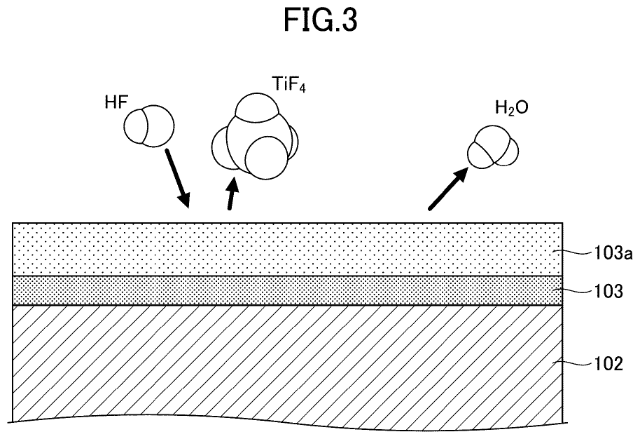

FIG. 3 is a cross-sectional view illustrating an example of the etching step S2. The etching step S2 may include HF processing. The HF processing may include supplying hydrogen fluoride gas to the substrate 101 while the substrate 101 is maintained at a first processing temperature. The first processing temperature is, for example, 200° C. or more and 300° C. or less. When hydrogen fluoride gas is supplied to the substrate 101, a reaction shown in Formula 1 occurs.

$${TiO}_{2} + 4 HF \to {TiF}_{4} + 2 {H}_{2} O \qquad ( 1 )$$

That is, as shown in FIG. 3, when hydrogen fluoride gas is supplied to the substrate 101, the titanium oxide film 103 reacts with the hydrogen fluoride gas to form volatile titanium fluoride (TiF₄) 103a, and the titanium oxide film 103 is etched. In this case, there is no need to change the temperature during the etching step S2. Therefore, a time required for etching the titanium oxide film 103 can be shortened.

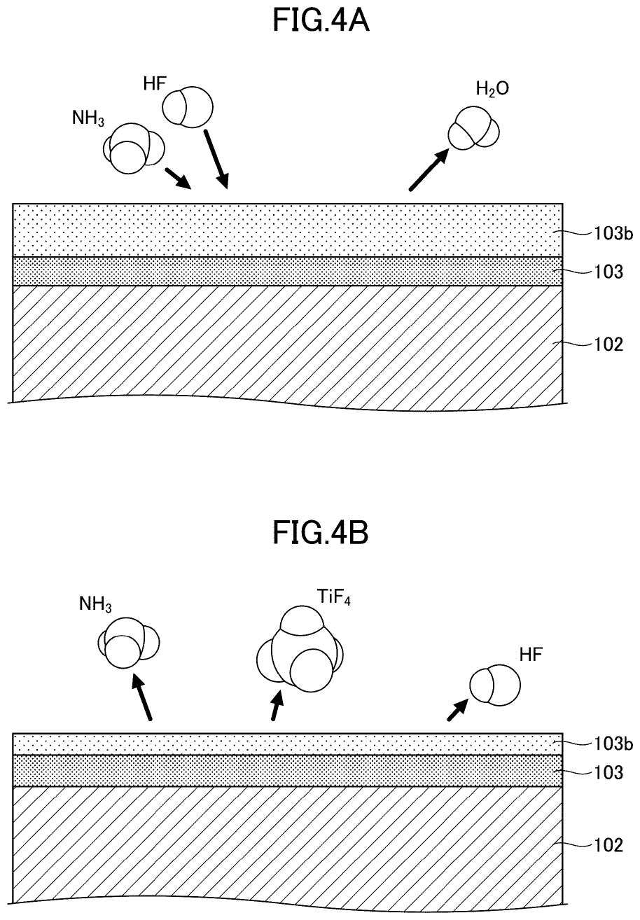

FIGS. 4A and 4B are cross-sectional views illustrating another example of the etching step S2. The etching step S2 may include a COR (Chemical Oxide Removal) processing and a PHT (Post Heat Treatment) processing. In the etching step S2, the COR processing and the PHT processing may be performed only once in this order, or the COR processing and the PHT processing may be repeated in this order. When the COR processing and the PHT processing are repeated in this order, a purge using an inert gas such as nitrogen (N₂) gas may be performed after the PHT processing but before the COR processing.

The COR processing is a processing for chemically etching without generating plasma. The COR processing may include supplying a gas mixture of hydrogen fluoride ammonia gas and (NH₃) gas (hereinafter, it is also referred to simply as “gas mixture”) to the substrate 101 while the substrate 101 is maintained at a second processing temperature. The second processing temperature is, for example, 50° C. or more and 70° C. or less. When the gas mixture is supplied to the substrate 101, reactions shown by Formulae 2 and 3 occur.

$${TiO}_{2} + 4 HF + 4 {NH}_{3} \to {TiF}_{4} + 2 {H}_{2} O + 4 {NH}_{3} \qquad ( 2 )$$

$${TiF}_{4} + 2 HF + 4 {NH}_{3} \to {( {NH}_{4} )}_{2} {TiF}_{6} \qquad ( 3 )$$

That is, as shown in FIG. 4A, when the gas mixture is supplied to the substrate 101, the titanium oxide film 103 reacts with the hydrogen fluoride gas and the ammonia gas to produce nonvolatile ammonium hexafluorotitanate [(NH₄)₂TiF₆] 103b. The ammonia gas is an example of a basic gas. The basic gas may be hydrazine (N₂H₄) gas.

The PHT processing may include heat treatment while the substrate 101 is maintained at a third processing temperature higher than the second processing temperature. The third processing temperature is the temperature at which ammonium hexafluorotitanate 103b sublimates, for example, from 200° C. to 300° C. When the substrate 101 is heat treated at the third processing temperature, the reaction shown in Formula 4 occurs.

$${( {NH}_{4} )}_{2} {TiF}_{6} \to {TiF}_{4} + 2 HF + 2 {NH}_{3} \qquad ( 4 )$$

That is, as shown in FIG. 4B, when the substrate 101 is heat treated at the third processing ammonium hexafluorotitanate 103b is temperature, sublimated and the titanium oxide film 103 is etched.

As described above, according to the substrate processing method according to the embodiment, etching gas including hydrogen fluoride gas is supplied to the substrate 101 in which the titanium nitride film 102 and the titanium oxide film 103 are stacked in this order to etch the titanium oxide film 103. In this case, the titanium oxide film 103 can be removed.

### [Substrate Processing Apparatus]

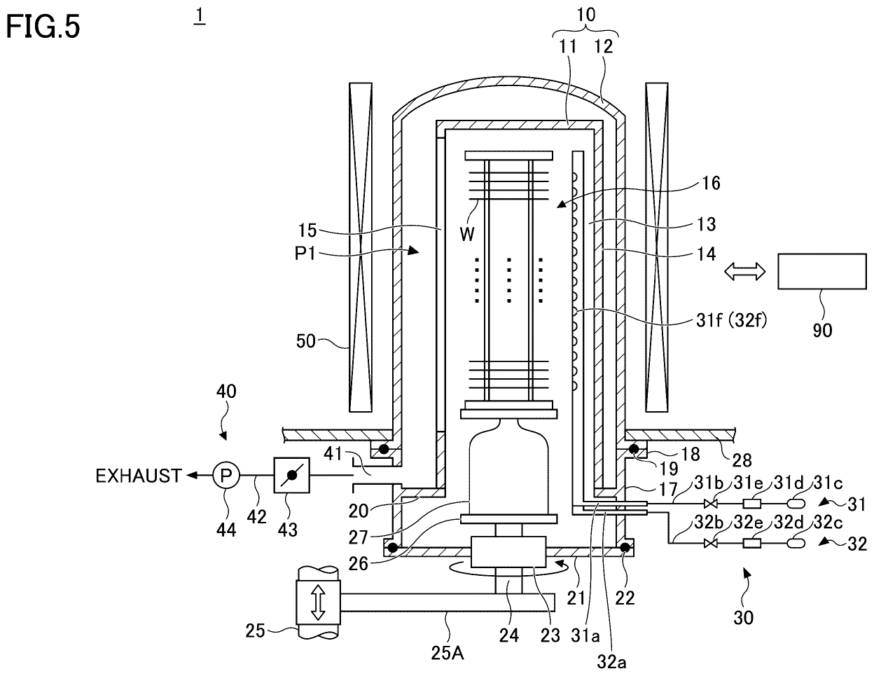

The substrate processing apparatus 1 according to the embodiment will be described with reference to FIG. 5. As shown in FIG. 5, the substrate processing apparatus 1 is a batch type apparatus that performs processing on substrates W all together.

The substrate processing apparatus 1 includes a processing vessel 10, a gas supply 30, an exhauster 40, a heating section 50, and a controller 90.

The processing vessel 10 can depressurize its inside. The processing vessel 10 houses the substrate W inside. The processing vessel 10 has an inner tube 11 and an outer tube 12. The inner tube 11 and the outer tube 12 have a cylindrical shape with a ceiling whose lower end is open. The outer tube 12 covers the outside of the inner tube 11. The inner tube 11 and the outer tube 12 have a double tube structure arranged coaxially. The inner tube 11 and the outer tube 12 are formed of a heat-resistant material such as quartz.

The ceiling of the inner tube 11 may be flat, for example. On one side of the inner tube 11, a receiver 13 for receiving the gas nozzle along the longitudinal direction (vertical direction) is formed. For example, a portion of a lateral wall of the inner tube 11 is projected outward to form a projection 14, and the inside of the projection 14 is formed as the receiver 13.

On the lateral wall opposite to the receiver 13, a rectangular opening 15 is formed along the longitudinal direction (vertical direction) of the inner tube 11.

The opening 15 is a gas exhaust port formed to discharge the gas in the inner tube 11. The length of the opening 15 is equal to the length of a boat 16, or is formed so as to extend vertically longer than the length of the boat 16.

The lower end of the processing vessel 10 is supported by a cylindrical manifold 17. The manifold 17 is formed of, for example, stainless steel. A flange 18 is formed at the upper end of the manifold 17. The flange 18 supports the lower end of the outer tube 12. A sealing member 19 such as an O-ring is provided between the flange 18 and the lower end of the outer tube 12. Thus, the inside of the outer tube 12 is kept airtight.

An annular support 20 is provided on the inner wall of the upper part of the manifold 17. The support 20 supports the lower end of the inner tube 11. A cover 21 is airtightly attached to the opening of the lower end of the manifold 17 via a sealing member 22 such as an O-ring. Thus, the opening at the lower end of the processing vessel 10, that is, the opening of the manifold 17, is hermetically closed. The cover 21 is formed of, for example, stainless steel.

A rotary shaft 24 is provided at the center of the cover 21 through a magnetic fluid seal 23. The lower part of the rotary shaft 24 is rotatably supported by an arm 25A of a lifting mechanism 25 including a boat elevator.

A rotary plate 26 is provided at the upper end of the rotary shaft 24. The boat 16 for holding the substrate W is placed on the rotary plate 26 through a quartz heat insulator 27. The boat 16 rotates by rotating the rotary shaft 24. The boat 16 moves up and down integrally with the cover 21 by raising and lowering the lifting mechanism 25. Thus, the boat 16 is inserted into and removed from the processing vessel 10. The boat 16 can be accommodated in the processing vessel 10. The boat 16 holds substrates W (e.g., 50 to 150 substrates) substantially horizontally at intervals in the vertical direction.

The gas supply 30 is configured so that various processing gases used in the substrate processing method can be introduced into the inner tube 11. The gas supply 30 includes a hydrogen fluoride supply 31 and an ammonia supply 32.

The hydrogen fluoride supply 31 includes a supply tube 31a inside the processing vessel 10 and a supply path 31b outside the processing vessel 10. The supply path 31b is provided with a hydrogen fluoride gas supply source 31c, a mass flow controller 31d and a valve 31e in sequence from upstream to downstream in the direction of gas flow. Thus, the supply timing of the hydrogen fluoride gas in the supply source 31c is controlled by the valve 31e, and adjusted to a predetermined flow rate by the mass flow controller 31d. The hydrogen fluoride gas flows into the supply tube 31a from the supply path 31b, and is discharged into the processing vessel 10 from the supply tube 31a.

The ammonia supply 32 includes a supply tube 32a inside the processing vessel 10 and a supply path 32b outside the processing vessel 10. The supply path 32b is provided with an ammonia gas supply source 32c, a mass flow controller 32d, and a valve 32e in sequence from upstream to downstream in the direction of gas flow. Thus, the supply timing of the ammonia gas in the supply source 32c is controlled by the valve 32e, and adjusted to a predetermined flow rate by the mass flow controller 32d. The ammonia gas flows into the supply tube 32a from the supply path 32b, and is discharged into the processing vessel 10 from the supply tube 32a.

The supply tubes 31a, 32a are fixed to the manifold 17. The supply tubes 31a, 32a are formed of, for example, quartz. The supply tubes 31a, 32a extend linearly in the vertical direction near the inner tube 11, and extend horizontally in the manifold 17 by bending in an L-shape, thereby penetrating the manifold 17. The supply tubes 31a, 32a are provided side by side along the circumferential direction of the inner tube 11 and are formed at the same height.

Discharge ports 31f, 32f are respectively provided at portions of the supply tubes 31a, 32a located within the inner tube 11. The discharge ports 31f, 32f are formed at predetermined intervals along the extending direction of the supply tubes 31a, 32a. The discharge ports 31f, 32f discharge gas in the horizontal direction. The interval between the discharge ports 31f, 32f is set equal to, for example, the interval between the substrates W held by the boat 16. The positions of the discharge ports 31f, 32f in the height direction are set at intermediate positions between the vertically adjacent substrates W. Thus, the discharge ports 31f, 32f can efficiently supply gas to the opposing surfaces between the adjacent substrates W.

The gas supply 30 may mix gases and discharge the gas mixture from one supply tube. The supply tubes 31a, 32a may have different shapes and arrangements. In addition to hydrogen fluoride gas and ammonia gas, the gas supply 30 may further include a supply tube for supplying other gases.

The exhauster 40 exhausts the gas discharged from the gas outlet 41 through the opening 15 from the inner tube 11 and through a space P1 between the inner tube 11 and the outer tube 12. The gas outlet 41 is a lateral wall of the upper part of the manifold 17 and is formed above the support 20. An exhaust passage 42 is connected to the gas outlet 41. A pressure regulating valve 43 and a vacuum pump 44 are successively interposed in the exhaust passage 42 to exhaust the inside of the processing vessel 10.

The heating section 50 is provided around the outer tube 12. The heating section 50 is provided, for example, on a base plate 28. The heating section 50 has a cylindrical shape so as to cover the outer tube 12. The heating section 50 includes a heater, for example, and heats each substrate W in the processing vessel 10.

The controller 90 is an electronic circuit such as a central processing unit (CPU), a field programmable gate array (FPGA), or an application specific integrated circuit (ASIC). The controller 90 executes various control operations described in the present description by executing an instruction code stored in a memory or by designing a circuit for a special application.

### [Operation of Substrate Processing Apparatus]

An example of the operation of the substrate processing method according to the embodiment in the substrate processing apparatus 1 will be described below.

First, the controller 90 controls the lifting mechanism 25 to carry the boat 16 holding the substrates W into the processing vessel 10, and hermetically closes the opening at the lower end of the processing vessel 10 with the cover 21 to seal it. Subsequently, the controller 90 controls the exhauster 40 to depressurize the inside of the processing, and controls the heating section 50 to adjust the temperature of the substrate W to a predetermined temperature. Each substrate W may be the substrate 101 described above.

Subsequently, the controller 90 controls the gas supply 30, the exhauster 40, and the heating section 50 so as to execute the etching step S2. Specifically, first, the controller 90 controls the heating section 50 to maintain the temperature of the substrate W at the first processing temperature, controls the gas supply 30 to supply hydrogen fluoride gas into the processing vessel 10, and controls the exhauster 40 to maintain the inside of the processing vessel 10 at the processing pressure. Thus, the titanium oxide film 103 reacts with the hydrogen fluoride gas to generate volatile titanium fluoride 103a, and the titanium oxide film 103 is etched.

Subsequently, the controller 90 boosts the inside of the processing vessel 10 to atmospheric pressure, lowers the inside of the processing vessel 10 to a removal temperature, and then controls the lifting mechanism 25 to remove the boat 16 from the processing vessel 10. Thus, the processing of the substrates W is completed.

### [Experimental Results]

### (Experiment 1)

In Experiment 1, substrates W11 to W15 were prepared in which a stacked film consisting of a titanium nitride film and a titanium oxide film stacked in this order was formed on the surface.

For substrate W11, oxygen concentration and fluorine concentration contained in the stacked film were measured by secondary ion mass spectrometry (SIMS) without performing the aforementioned etching step S2.

For substrates W12 to W15, oxygen concentration and fluorine concentration contained in the stacked film were measured by SIMS after performing the aforementioned etching step S2. Conditions of the etching step S2 for substrates W12 to W15 were as follows.

### (Substrate W12)

COR processing+PHT processing
Substrate temperature for COR processing: 65° C.
COR processing time: one minute

### (Substrate W13)

COR processing+PHT processing
Substrate temperature for COR processing: 65° C.
COR processing time: ten minutes

### (Substrate W14)

HF processing
Substrate temperature for HF processing: 200° C.
HF processing time: five minutes

### (Substrate W15)

HF processing
Substrate temperature for HF processing: 250° C.
HF processing time: three minutes

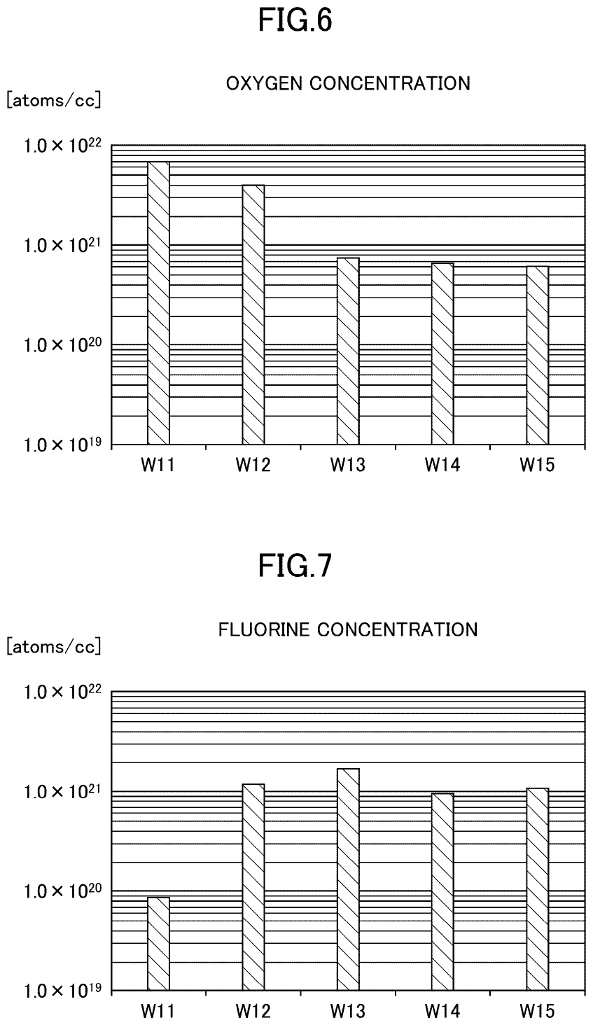

FIG. 6 is a drawing illustrating an example of the result of measuring oxygen concentration. FIG. 6 shows the oxygen concentration [atoms/cc] contained in the stacked film on the substrates W11 to W15 in logarithmic scale. FIG. 7 is a drawing illustrating an example of a result of measuring fluorine concentration. FIG. 7 shows the fluorine concentration [atoms/cc] contained in the stacked film on the substrates W11 to W15 in logarithmic scale.

As shown in FIG. 6, the oxygen concentration in the substrates W12 to W15 is lower than that in the substrate W11. From these results, it can be concluded that oxygen can be removed from the stacked film in both cases: when COR processing and PHT processing are performed, and when HF processing is performed as the etching step S2.

As shown 7, in FIG. the fluorine concentration in the substrates W12 to W15 is higher than that in the substrate W11. From this result, it is considered that fluorine can be introduced into the stacked film in both cases of COR and PHT processing and HF processing as the etching step S2.

From the above results, it is considered that the substrate processing method according to the embodiment can simultaneously remove titanium oxide film from the stacked film and introduce fluorine into the titanium nitride film.

### (Experiment 2)

In Experiment 2, a substrate with a titanium oxide (TiO) film formed on the surface, a substrate with a titanium nitride (TiN) film formed on the surface, and a substrate with a silicon nitride (SiN) film formed on the surface were prepared. Subsequently, HF processing was performed on each substrate as the aforementioned etching step S2. In the HF processing, the substrate temperature was maintained at 200° C. In addition, an etching amount of each film was calculated by subtracting the film thickness of each film (silicon nitride film, titanium nitride film, and titanium oxide film) after the etching step S2 from the film thickness of each film before the etching step S2.

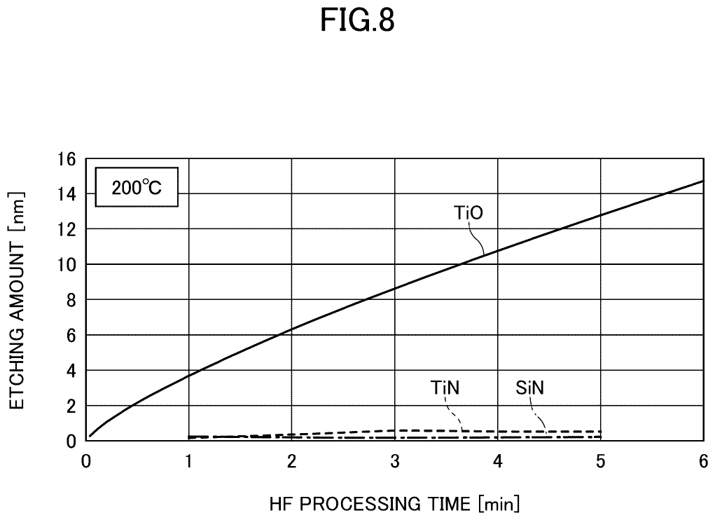

FIG. 8 is a drawing illustrating the result of measuring the etching amount of each film. In FIG. 8, the horizontal axis indicates the HF processing time [min], and the vertical axis indicates the etching amount [nm]. In FIG. 8, a solid line indicates the etching amount of the titanium oxide film, a dashed line indicates the etching amount of the titanium nitride film, and an alternate long and short dash line indicates the etching amount of the silicon nitride film.

As shown in FIG. 8, the etching amount of the titanium oxide film increases with increasing HF processing time, while the etching amount of the titanium nitride film hardly changes with increasing HF processing time. From this result, it is considered that by performing HF processing as the etching step S2, the titanium oxide film can be selectively etched and removed from the stacked film in which the titanium nitride film and the titanium oxide film are stacked in this order, while leaving the titanium nitride film.

Also, as shown in FIG. 8, the etching amount 4 silicon nitride film hardly changes with increasing HF processing time. From this result, it is considered that the titanium oxide film can be selectively etched and removed from the silicon nitride film.

### (Experiment 3)

In Experiment 3, each film was subjected to HF processing under the same conditions as in Experiment 2 except that the substrate temperature was set at 250° C. for HF processing, and the etching amount of each film was calculated.

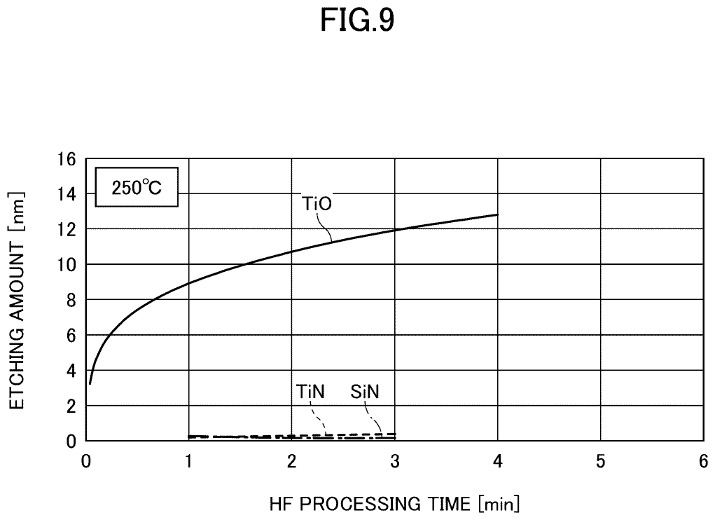

FIG. 9 is a drawing illustrating the result of measuring the etching amount of each film. In FIG. 9, the horizontal axis indicates the HF processing time [min], and the vertical axis indicates the etching amount [nm]. In FIG. 9, the solid line indicates the etching amount of the titanium oxide film, the dashed line indicates the etching amount of the titanium nitride film, and the dashed line indicates the etching amount of the silicon nitride film.

As shown in FIG. 9, the etching amount of the titanium oxide film increases with increasing HF processing time, while the etching amount of the titanium nitride film hardly changes with increasing HF processing time. From this result, it is considered that by performing HF processing in the etching step S2, the titanium oxide film can be selectively etched and removed from the stacked film in which the titanium nitride film and the titanium oxide film are stacked in this order while leaving the titanium nitride film.

As shown in FIG. 9, the etching amount of the silicon nitride film, as well as the titanium nitride film, hardly changes with increasing HF processing time. From this result, it is considered that the titanium oxide film can be selectively etched and removed from the silicon nitride film.

A hafnium oxide (HfO₂) film, a zirconium oxide (ZrO₂) film, and an aluminum oxide (AlO₃) film are also hardly etched by HF processing. Conceivably, it is because when the hafnium oxide film, the zirconium oxide film, and the aluminum oxide film react with hydrogen fluoride gas, stable nonvolatile aluminum fluoride (AlF₃), hafnium fluoride (HfF₄) and zirconium fluoride (ZrF₄) are formed, respectively. As a result, the titanium oxide film can be selectively etched and removed from the hafnium oxide film, the zirconium oxide film, and the aluminum oxide film.

The present disclosure is not limited to these embodiments, but various variations and modifications may be made without departing from the scope of the present invention.

In the above embodiment, a case where the substrate: processing apparatus is a batch type apparatus for processing substrates all together has been described, but this disclosure is not limited thereto. For example, the substrate processing apparatus may be a single wafer type apparatus for processing substrates one by one. For example, the substrate processing apparatus may be a semi-batch type apparatus in which substrates arranged on a rotation table in the processing vessel are rotated by the rotation table, and the substrates are processed by passing through processing regions arranged along the rotation direction of the rotation table in order.

According to the present disclosure, the titanium oxide film can be removed.

1. A method of processing a substrate, the method comprising:
preparing the substrate in which a titanium nitride film and a titanium oxide film are stacked in this order; and
supplying an etching gas containing a hydrogen fluoride gas to the substrate to etch the titanium oxide film.

2. The method of processing the substrate according to claim 1, wherein the titanium oxide film is a natural oxide film formed on a surface of the titanium nitride film.

3. The method of processing the substrate according to claim 1, wherein the preparing includes:
forming the titanium nitride film on the substrate; and
exposing the titanium nitride film to an oxidizing atmosphere.

4. The method of processing the substrate according to claim 1, wherein:
the etching gas is the hydrogen fluoride gas; and
the etching includes generating titanium fluoride by reacting the titanium oxide film with the hydrogen fluoride gas.

5. The method of processing the substrate according to claim 4, wherein the etching includes maintaining temperature of the substrate at 200° C. to 300° C.

6. The method of processing the substrate according to claim 1, wherein:
the etching gas is a gas mixture of the hydrogen fluoride gas and a basic gas;
the etching includes generating ammonium hexafluorotitanate by reacting the titanium oxide film with the gas mixture.

7. The method of processing the substrate according to claim 6, wherein the etching includes sublimating the ammonium hexafluorotitanate after supplying the gas mixture to the substrate.

8. An apparatus for processing a substrate, the apparatus comprising:
a processing vessel configured to house the substrate;
a gas supply configured to supply an etching gas containing a hydrogen fluoride gas into the processing vessel; and
a controller,
wherein the controller is configured to execute:
housing in the processing vessel the substrate in which a titanium nitride film and a titanium oxide film are stacked in this order; and
supplying the etching gas to the substrate housed in the processing vessel and etching the titanium oxide film.
